(19) United States
(12) Patent Application Publication
(10) Pub. No.: US 2005/0245073 A1
(43) Pub. Date: Nov. 3, 2005

(54) Method for forming contact plug of semiconductor device

(76) Inventors: Seok Kiu Lee, Kyoungki-do (KR); Tae Hang Ahn, Seoul (KR); Sung Eon Park, Seoul (KR); Jun Hee Cho, Seoul (KR); Yil Wook Kim, Seoul (KR)

Correspondence Address: LADAS & PARRY LLP, 224 SOUTH MICHIGAN AVENUE, SUITE 1600, CHICAGO, IL, 60604, US

(21) Appl. No.: 11/000,301

(22) Filed: Nov. 30, 2004

(30) Foreign Application Priority Data
Apr. 28, 2004 (KR) 2004-29600

(51) Int. Cl. H01L 21/336

(52) U.S. Cl. 438/629

(57) ABSTRACT

In a method for forming a contact plug of a semiconductor device, epitaxial silicon is formed as contact material using a solid-phase epitaxy method. The method can obtain reduced contact resistance and improved refresh characteristics, compared with prior arts using polysilicon as contact material. Also, the method uses an SPE method, not a conventional SEG method, to form epitaxial silicon so that it can substantially reduce thermal budget through low-temperature processes. The method can also use conventional polysilicon deposition process without modification to form epitaxial silicon with ease and productivity.

### BACKGROUND OF THE INVENTION

1. Field of the invention

The present invention relates to a method for forming a contact plug of a semiconductor device, and more particularly to a method for forming epitaxial silicon as contact material using a solid-phase epitaxy method.

2. Description of the Prior Art

As semiconductor devices are highly integrated, it has become difficult to secure the characteristics of the devices. In the case of a DRAM cell transistor, for example, cell contact area decreases as the size of the cell transistor is gradually reduced. Consequently, a rapid increase in contact resistance followed by rapid decrease in operating current of the cell transistor is expected. In spite of the decrease in size of the cell transistor, downward adjustment of the operating voltage is performed very slowly and there is concern that refresh characteristics may deteriorate due to the increase in local electric field. In summary, it has become difficult to satisfy both the operating current and the refresh characteristics of the cell transistor as the DRAM is highly integrated.

In order to increase the operating current of the cell transistor while maintaining the threshold voltage Vt thereof, following measures are necessary: firstly, the concentration of impurities in the junction region is increased to reduce a sheet resistance; secondly, the contact interface is cleaned; thirdly, the doping concentration of phosphorus (P) within polysilicon, which is used as a cell contact landing plug, is increased to reduce the contact resistance between the junction region and the landing plug.

The above measures for increased operating current of the cell transistor, on the contrary, act as factors which deteriorate the refresh characteristics of the DRAM. Specifically, there is a tradeoff between the operating current and the refresh characteristics of the cell transistor, and it is substantially difficult to simultaneously improve both of them. Accordingly, cell transistor manufacturing process is currently optimized by properly regulating the operating current and the refresh characteristics in such a manner that they meet the device specification.

In an attempt to improve both the operating current and the refresh characteristics, a method for obtaining a clean contact interface before growth of the polysilicon, which is landing plug material, to remove etching remnants as much as possible is tried in combination with a method for optimizing the doping concentration of phosphorus (P) within polysilicon and that within the junction region, as well as the profile.

However, process margin abruptly narrows in a design rule of less than 0.15 μm and it is believed that new process or material is necessary.

In order to secure both the operating current and the refresh characteristics of the cell transistor, a technology using a new process has been proposed including a method of performing boron cell halo ion injection only to the junction region of a bit-line contact portion and a method of using a RCAT (recessed channel array transistor) technology wherein the channel between two junction regions of source/drain is made in a trench shape to increase the channel length and alleviate local electrical field concentration. However, such new processes are not currently adapted with ease due to the complexities of the process.

In an attempt to solve the problems with new material, it has been proposed to replace the polysilicon, which is used as landing plug material, with epitaxial silicon (that is, monocrystalline silicon). Experiments have shown that an epitaxial silicon landing plug has a contact resistance value, corresponding to 2/5 of that of a polysilicon landing plug at a phosphorus (P) doping concentration value corresponding to 1/5 of that of the latter (refer to FIG. 1).

When epitaxial silicon is used as landing plug material, the diffusion of phosphorus (P) from the landing plug into the junction region also decreases due to low phosphorus (P) doping concentration, in addition to the advantage of low contact resistance. This substantially decreases leakage current and simultaneously improves the refresh characteristics.

In order to grow epixatial silicon as landing plug material, a selective epitaxial growth (hereinafter, referred to as SEG) method has been conventionally used. In the SEG method, epitaxial silicon selectively grows on a silicon junction region, which has been subject to a suitable pre-cleaning, while injecting SiH₂Cl₂, PH₃, and HCl gases as reaction gases into a hydrogen gas atmosphere at a temperature of 800-900° C.

As the epitaxial growth progresses, monocrystal silicon which is the same as the substrate grows on exposed silicon, however, no silicon grows on insulation film including silicon oxide film and silicon nitride film, because the rate of etching of polysilicon by HCl is faster than the rate of nucleus creation and growth of polysilicon. Consequently, epitaxial silicon selectively grows only on the exposed silicon.

In order to grow productive film with the SEG method, however, there are many problems to be solved as follows: firstly, a dummy pattern needs to be designed due to the pattern dependence of film growth rate and thickness uniformity; secondly, proper pre-cleaning before selective epitaxial silicon growth is necessary, specifically, light etching, fluoride-based (HF, BOE, HF vapor) wet cleaning, and in-situ hydrogen bake before selective epitaxial growth are necessary; thirdly, abnormal growth on the insulating surface must be suppressed by precisely controlling contamination by metal; fourthly, there is a burden of the deterioration of characteristics of the short channel transistor caused by high-temperature (800° C. or above) in-situ hydrogen bake and epitaxial silicon growth temperature; fifthly, there is difficulty in integrating processes because of facet formation; and sixthly, if epitaxial silicon does not grow on some faulty contacts among many contacts, a problem may occur in the following process. The SEG method also needs some special equipment technology which is hard to use.

In summary, although contact resistance may decrease and refresh may improve simultaneously when epitaxial silicon is used as cell contact landing plug material, this method cannot be easily adopted in mass production because of the above-mentioned problems.

### SUMMARY OF THE INVENTION

Accordingly, the present invention has been made to solve the above-mentioned problems occurring in the prior art, and an object of the present invention is to provide a method for forming a contact plug of a semiconductor device capable of obtaining low contact resistance and excellent refresh characteristics by using epitaxial silicon as contact material.

Another object of the present invention is to provide a method for forming a contact plug of a semiconductor device capable of growing epitaxial silicon as contact material using conventional processes without modification for easy and productive formation of epitaxial silicon.

In order to accomplish this object, there is provided a method for forming a contact plug of a semiconductor device comprising the steps of: providing a silicon substrate having a plurality of conductive patterns and a junction region between the conductive patterns; forming an interlayer insulation film on the substrate; forming a contact hole to expose the junction region of the substrate; depositing a silicon film on the whole substrate including the contact hole using a solid-phase epitaxy method in such a manner that epitaxial silicon grows on the junction region of the substrate and amorphous silicon is deposited thereon; and annealing the resulting structure to re-grow the amorphous silicon into epitaxial silicon.

The step of depositing a silicon film is performed at a pressure of 1-100 Torr and a temperature of 550-650° C.

The step of depositing a silicon film is performed with a phosphorus doping concentration of 1E19-1E20 atom/cm³.

The step of annealing to re-grow the amorphous silicon into epitaxial silicon is performed in an inert gas atmosphere at a temperature of 500-700° C. for at least 30 minutes.

Also, in order to accomplish this object, there is provided a method for forming a contact plug of a semiconductor device comprising the steps of: providing a silicon substrate having a plurality of gate electrodes; depositing an insulation film on the resulting structure; forming a junction region in a region of the substrate between the gate electrodes; forming an interlayer insulation film on the resulting structure; forming a contact hole to expose the junction region of the substrate; cleaning the exposed junction region of the substrate; depositing a silicon film on the whole substrate including the contact hole using a solid-phase epitaxy method in such a manner that epitaxial silicon grows on the junction region of the substrate and amorphous silicon is deposited thereon; and annealing the resulting structure to re-grow the amorphous silicon into epitaxial silicon.

The step of depositing a silicon film is performed at a pressure of 1-100 Torr and a temperature of 550-650° C.

The step of depositing a silicon film is performed with a phosphorus doping concentration of 1E19-1E20 atom/cm³.

The step of annealing to re-grow the amorphous silicon into epitaxial silicon is performed in an inert gas atmosphere at a temperature of 500-700° C. for at least 30 minutes.

Further, in order to accomplish this object, there is provided a method for forming a contact plug of a semiconductor device comprising the steps of: providing a silicon substrate having a plurality of gate electrodes formed thereon; depositing an gate sealing insulation film on the whole substrate including the gate electrodes; forming a junction region in a region of the substrate between the gate electrodes; depositing a gate spacer film and an interlayer insulation film on the resulting structure; etching the interlayer insulation film, the gate spacer film, the gate sealing insulation film, to form a landing plug contact which exposes the plurality of gate electrodes and the junction region of the substrate between the gate electrodes; performing pre-cleaning and hydrogen bake on the exposed contact area of the substrate; depositing a silicon film on the whole substrate, including the landing plug contact, using a solid-phase epitaxy method in such a manner that epitaxial silicon grows on the junction region of the substrate and amorphous silicon is deposited thereon; performing re-crystallization annealing on the resulting structure to re-grow the amorphous silicon within the landing plug contact into epitaxial silicon; and removing epitaxial silicon from the top of the gate electrodes.

The step of pre-cleaning comprises light etching using any reaction gas selected from a group consisting of NF₃/He/O₂-based reaction gas, CF₄/O₂-based reaction gas, and Ar/O₂-based reaction gas in a remote plasma or low-power plasma state and fluoride-based cleaning using any one selected from a group consisting of HF solution, BOE solution, and HF steam.

The resulting structure is loaded into deposition equipment at least within four hours after the pre-cleaning and, during the loading, a vacuum is maintained or, when the substrate is loaded in an atmospheric pressure state, it is purged with inert gas of high-purity nitrogen or argon, while maintaining oxygen density at below 10ppm.

The step of depositing a silicon film is performed at a pressure of 1-100 Torr and a temperature of 550-650° C.

The step of depositing a silicon film is performed with a phosphorus (P) doping concentration of 1E19-1E20 atom/cm³.

The step of performing re-crystallization annealing to re-grow the amorphous silicon into epitaxial silicon is performed in an inert gas atmosphere at a temperature of 500-700° C. for at least 30 minutes.

### BRIEF DESCRIPTION OF THE DRAWINGS

The above and other objects, features and advantages of the present invention will be more apparent from the following detailed description taken in conjunction with the accompanying drawings, in which:

FIG. 1 is a graph showing the contact resistance of epitaxial silicon and polysilicon versus phosphorus (P) doping concentration; and

FIGS. 2A to 2F are sectional views illustrating a series of processes of a method for forming a contact plug according to an embodiment of the present invention.

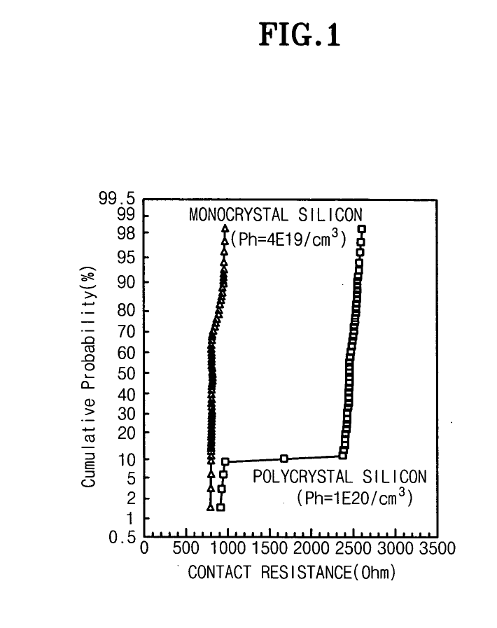

### DETAILED DESCRIPTION OF THE PREFERRED EMBODIMENTS

Hereinafter, a preferred embodiment of the present invention will be described with reference to the accompanying drawings. In the following description and drawings, the same reference numerals are used to designate the same or similar components, and so repetition of the description on the same or similar components will be omitted.

According to the present invention, epitaxial silicon is formed as contact material, i.e., as cell contact landing plug material. In order to form epitaxial silicon, a solid-phase epitaxy (hereinafter, referred to as SPE) method is used wherein amorphous silicon having a suitable range of phosphorus (P) needed by a device at low temperature is deposited on a contact interface, which has been subject to selective pre-cleaning, and epitaxial silicon is subsequently formed through re-crystallization annealing at low temperature. The present invention also makes it possible to stabilize the growth of epitaxial silicon by obtaining a contact interface which has been extremely cleaned before the growth of epitaxial silicon.

By using epitaxial silicon as contact material in this manner, it is possible to reduce contact resistance while improving refresh characteristics. In addition, epitaxial silicon can be easily formed with productivity using conventional processes adapted for low temperature (700° C. or less) without modification.

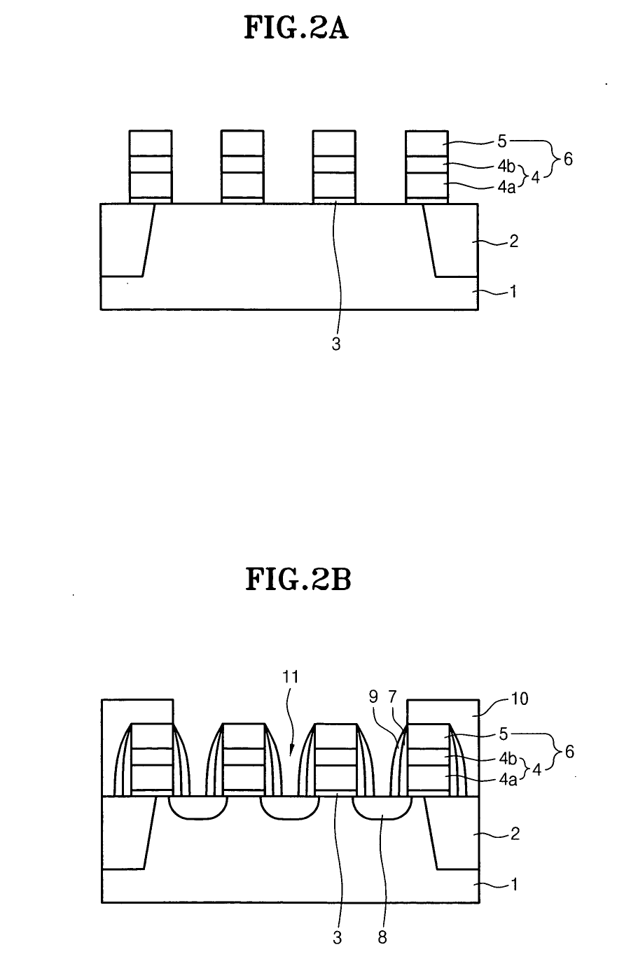

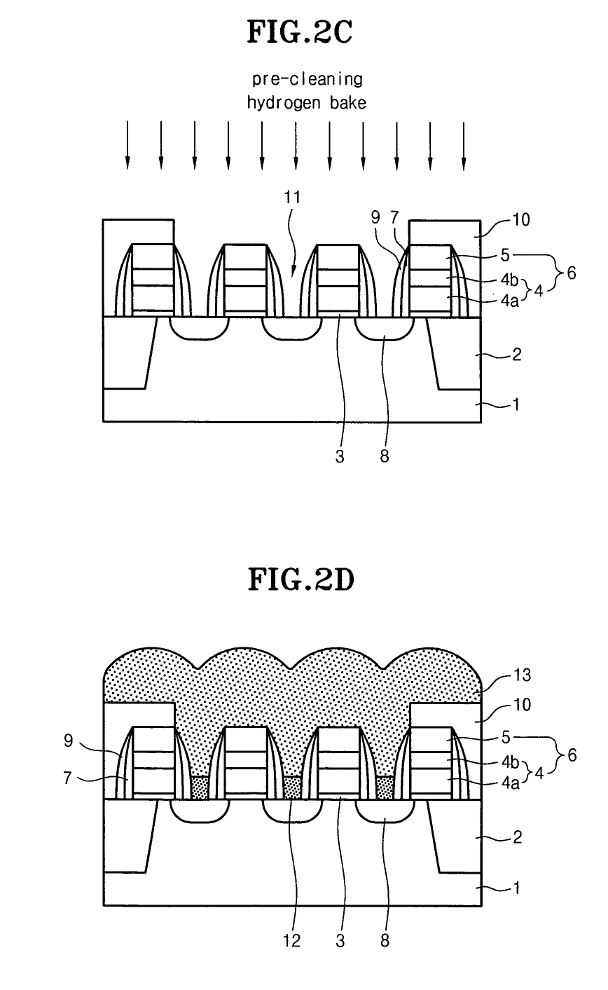

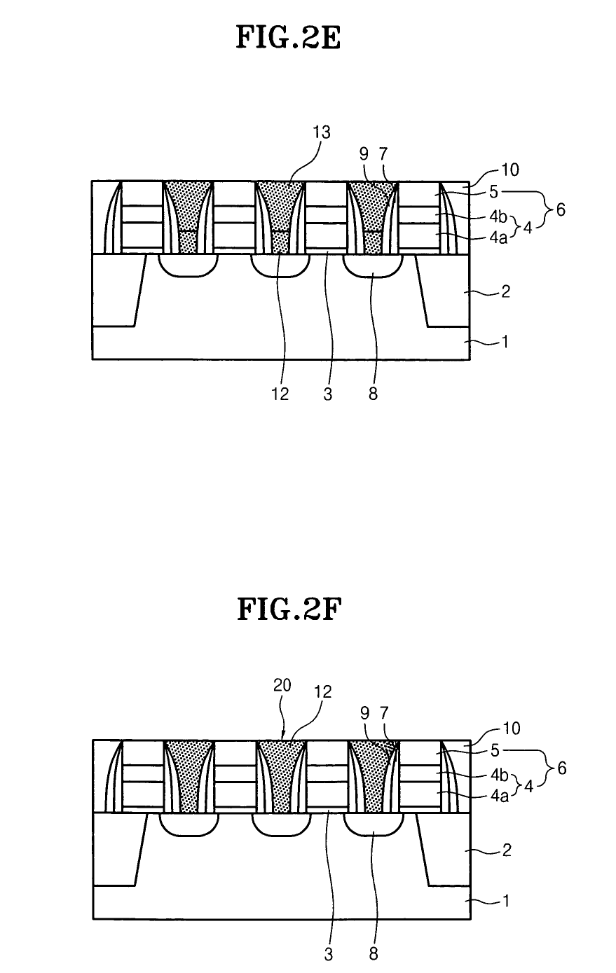

A method for forming a contact plug according to an embodiment of the present invention will now be described in detail with reference to FIGS. 2A to 2F, which are sectional views illustrating a series of processes of the method.

Referring to FIG. 2A, a device isolation film 2 is formed in a predetermined position of a silicon substrate 1 using an STI (shallow trench isolation) process. Then, several ion implantation processes are performed in a series. Thereafter, a gate oxide film 3, a gate conductive film 4, and a hard mask nitride film 5 are formed on the whole silicon substrate 1 successively and are patterned to form a gate electrode 6 as a conductive pattern.

The gate conductive film 4 may be composed of a single film made up of polysilicon film 4a or metallic film 4b. Alternatively, the gate conductive film 4 may be formed by stacking polysilicon film 4a and metallic film 4b. The metallic film 4b is made up of metal silicide or refractory metal, which has excellent stability at high temperature.

Referring to FIG. 2B, a thermal oxidation or CVD process is performed to form a gate buffering oxidation film (not shown) and a nitride film 7 as a gate sealing insulation film is deposited on the resulting structure. Then, ion implantation is performed to form a junction region 8. The impurity doping profile in the junction region 8 becomes gentle, the electric field concentration at the end of the gate electrode 6 is alleviated, and the leakage current in the junction region 8 is reduced.

Although not shown in the drawing, a junction region for a transistor in the peripheral circuit portion is formed using a convention method, and a gate spacer nitride film 9 is formed on the whole substrate. An interlayer insulation film 10 is then deposited on the gate spacer nitride film 9. Using a landing plug contact process, the interlayer insulation film 10, the gate spacer nitride film 9, the gate sealing nitride film 7, and the gate buffering oxide film are successively subject to dry etching to form a contact hole, i.e., a landing plug contact 11, which exposes a plurality of gate electrodes 6 and the junction region 8 of the substrate between the gate electrodes 6.

Referring to FIG. 2C, selective pre-cleaning is performed on the resulting structure, which has the landing plug contact 11 formed thereon, to obtain a clean contact interface. The resulting structure is then loaded into silicon deposition equipment, which is capable of loading the substrate in vacuum, and in-situ hydrogen bake is performed in this state.

Process condition for the pre-cleaning process is set for the purpose of complete removal of etching remnants occurring when etching the landing plug contact, removal of etching damage, and removal of native oxide film on the cell contact surface. Specifically, etching remnants and etching damage are removed by light etching using NF₃/He/O₂-based, CF₄/O₂-based, or Ar/O₂-based reaction gas in a remote plasma or low-power plasma state. During the light etching, polymer-related etching remnants including C—F, C—O, and C—C, which occur during the cell contact etching, are removed. After the light etching, a silicon oxide film of about 1-4 nm is formed on the cell contact silicon surface, due to oxygen gas supplied during the light etching. Therefore, the light etching must be followed by fluoride-based pre-cleaning, such as wet cleaning using HF or BOE solution or steam cleaning using HF steam, in order to remove the silicon oxide film formed on the cell contact silicon surface.

It is also necessary to suppress contamination or interface oxide film creation from loading of the substrate, which has been subject to the above-mentioned pre-cleaning, into silicon deposition equipment, until deposition. To this end, the substrate must be loaded into the deposition equipment at least within four hours after the pre-cleaning. During the loading, a vacuum state must be maintained or, if the substrate is loaded in an atmospheric pressure state, it must be purged with inert gas, such as high-purity nitrogen or argon, while maintaining oxygen density at or below 10 ppm. This is because, if oxygen density in atmosphere is 10 ppm or above when the substrate is put into a high-temperature (400° C. or above) reaction chamber, an interface oxide film of 0.5 nm or above is formed on the contact interface. In this case, silicon substrate in the junction region cannot act as a seed in the subsequent thermal process for epitaxial silicon growth, and the whole cell contact landing plug is crystallized into polysilicon. Therefore, hydrogen bake is performed at a temperature of 750° C. or above after the substrate is loaded, before silicon film is deposited on it, in order to remove the interface oxide film more certainly. In this process, any interface oxide film generated when transferring the substrate after the pre-cleaning and when loading it into the deposition equipment is completely removed.

Referring to FIG. 2D, silicon films 12 and 13 are deposited on the interlayer insulation film 10 including the landing plug contact 11. In the contact interface, the monocrystalline silicon of the junction region 8 of the substrate acts as a seed and epitaxial silicon 12 grows, with amorphous silicon 13 deposited upon it. The deposition of silicon film must be performed at a pressure of 1-100 Torr and a temperature of 550-650° C. so that epitaxial silicon 12 grows on the contact interface and amorphous silicon 13 is deposited elsewhere. The phosphorus (P) doping concentration within film must be regulated in the range of 1E19-1E20 atom/cm³, considering the total amount of heat energy supplied in the subsequent device integration process, i.e., the thermal budget.

Referring to FIG. 2E, after undergoing the above processes, the resulting structure is subject to re-crystallization annealing in a inert atmosphere at a temperature of 700° C. or below, preferably of 500-700° C., for at least 30 minutes. In this annealing, amorphous silicon is re-crystallized into epitaxial silicon 12 as the epitaxial silicon, which has grown on the contact interface, acts as a seed.

During the re-crystallization of upper amorphous silicon into epitaxial silicon due to the epitaxial silicon seed, nucleus creation and crystal growth may occur at the interface between the gate spacer nitride film 9 or the interlayer nitride film 10 and the amorphous silicon. In this case, polysilicon may grow within the landing plug contact and the contact resistance of the landing plug may increase. Therefore, the process condition of re-crystallization heat treatment, specifically, re-crystallization temperature and time, must be properly regulated in such a manner that such formation of polysilicon can be avoided.

Referring to FIG. 2F, the resulting structure is subject to etch-back or chemical mechanical polishing process to remove epitaxial silicon from the top of the gate electrode 6. As a result, the inventive landing plug 20 made up of epitaxial silicon 12 is formed.

Thereafter, a series of conventional processes are performed to complete a semiconductor device.

As mentioned above, the present invention uses epitaxial silicon as contact material and thereby can obtain reduced contact resistance and improved refresh characteristics, compared with prior arts using polysilicon as contact material.

In addition, the present invention uses an SPE method, not a conventional SEG method, to form epitaxial silicon so that it can substantially reduce thermal budget through low-temperature processes. The present invention can also use conventional polysilicon deposition process without modification to form epitaxial silicon with ease and productivity.

Although a preferred embodiment of the present invention has been described for illustrative purposes, those skilled in the art will appreciate that various modifications, additions and substitutions are possible, without departing from the scope and spirit of the invention as disclosed in the accompanying claims.

1. A method for forming a contact plug of a semiconductor device comprising the steps of:
providing a silicon substrate having a plurality of conductive patterns and a junction region between the conductive patterns;
forming an interlayer insulation film on the substrate;
forming a contact hole to expose the junction region of the substrate;
depositing a silicon film on the whole substrate including the contact hole using a solid-phase epitaxy method in such a manner that epitaxial silicon grows on the junction region of the substrate and amorphous silicon is deposited thereon; and
annealing the resulting structure to re-grow the amorphous silicon into epitaxial silicon.

2. The method according to claim 1, wherein the step of depositing a silicon film is performed at a pressure of 1-100 Torr and a temperature of 550-650° C.

3. The method according to claim 1, wherein the step of depositing a silicon film is performed with a phosphorus doping concentration of 1E19-1E20 atom/cm³.

4. The method according to claim 1, wherein the step of annealing to re-grow the amorphous silicon into epitaxial silicon is performed in an inert gas atmosphere at a temperature of 500-700° C. for at least 30 minutes.

5. A method for forming a contact plug of a semiconductor device comprising the steps of:
providing a silicon substrate having a plurality of gate electrodes;
depositing an insulation film on the resulting structure;
forming a junction region in a region of the substrate between the gate electrodes;
forming an interlayer insulation film on the resulting structure;
forming a contact hole to expose the junction region of the substrate;
cleaning the exposed junction region of the substrate;
depositing a silicon film on the whole substrate including the contact hole using a solid-phase epitaxy method in such a manner that epitaxial silicon grows on the junction region of the substrate and amorphous silicon is deposited thereon; and
annealing the resulting structure to re-grow the amorphous silicon into epitaxial silicon.

6. The method according to claim 5, wherein the step of depositing a silicon film is performed at a pressure of 1-100 Torr and a temperature of 550-650° C.

7. The method according to claim 5, wherein the step of depositing a silicon film is performed with a phosphorus doping concentration of 1E19-1E20 atom/cm³.

8. The method according to claim 5, wherein the step of annealing to re-grow the amorphous silicon into epitaxial silicon is performed in an inert gas atmosphere at a temperature of 500-700° C. for at least 30 minutes.

9. A method for forming a contact plug of a semiconductor device comprising the steps of:
providing a silicon substrate having a plurality of gate electrodes formed thereon;
depositing an gate sealing insulation film on the whole substrate including the gate electrodes;
forming a junction region in a region of the substrate between the gate electrodes;
depositing a gate spacer film and an interlayer insulation film on the resulting structure;
etching the interlayer insulation film, the gate spacer film, the gate sealing insulation film, to form a landing plug contact which exposes the plurality of gate electrodes and the junction region of the substrate between the gate electrodes;
performing pre-cleaning and hydrogen bake on the exposed contact area of the substrate;
depositing a silicon film on the whole substrate, including the landing plug contact, using a solid-phase epitaxy method in such a manner that epitaxial silicon grows on the junction region of the substrate and amorphous silicon is deposited thereon;
performing re-crystallization annealing on the resulting structure to re-grow the amorphous silicon within the landing plug contact into epitaxial silicon; and
removing epitaxial silicon from the top of the gate electrodes.

10. The method according to claim 9, wherein the step of pre-cleaning comprises light etching using any reaction gas selected from a group consisting of NF₃/He/O₂-based reaction gas, CF₄/O₂-based reaction gas, and Ar/O₂-based reaction gas in a remote plasma or low-power plasma state and fluoride-based cleaning using any one selected from a group consisting of HF solution, BOE solution, and HF steam.

11. The method according to claim 9, wherein the resulting structure is loaded into deposition equipment at least within four hours after the pre-cleaning and, during the loading, a vacuum is maintained or, when the substrate is loaded in an atmospheric pressure state, it is purged with inert gas of high-purity nitrogen or argon, while maintaining oxygen density at below 10 ppm.

12. The method according to claim 9, wherein the step of depositing a silicon film is performed at a pressure of 1-100 Torr and a temperature of 550-650° C.

13. The method according to claim 9, wherein the step of depositing a silicon film is performed with a phosphorus (P) doping concentration of 1E19-1E20 atom/cm³.

14. The method according to claim 9, wherein the step of performing re-crystallization annealing to re-grow the amorphous silicon into epitaxial silicon is performed in an inert gas atmosphere at a temperature of 500-700° C. for at least 30 minutes.
